(19) United States
(12) Patent Application Publication
(10) Pub. No.: US 2022/0293766 A1
(43) Pub. Date: Sep. 15, 2022

(54) Semiconducting Ferroelectric Device

(71) Applicant: Cerfe Labs, Inc., Austin, TX (US)

(72) Inventors: Lucian Shifren, San Jose, CA (US); Carlos A. Paz de Araujo, Colorado Springs, CO (US); Jolanta B. Celinska, Colorado Springs, CO (US)

(21) Appl. No.: 17/695,497

(22) Filed: Mar. 15, 2022

Related U.S. Application Data
(60) Provisional application No. 63/161,113, filed on Mar. 15, 2021.
(60) Provisional application No. 63/161,125, filed on Mar. 15, 2021.
(60) Provisional application No. 63/161,135, filed on Mar. 15, 2021.
(60) Provisional application No. 63/212,959, filed on Jun. 21, 2021.

(51) Int. Cl. H01L 29/51; H01L 29/78; H01L 29/66; H01L 27/11585

(52) U.S. Cl. CPC H01L 29/516; H01L 29/78391; H01L 29/6684; H01L 27/11585

(57) ABSTRACT

A device stack for an electronic memory or other device includes a substrate and first and second layers of insulating material. The first layer of insulating material is supported by the substrate. A semiconducting ferroelectric layer is positioned and electrically isolated between the first and second layers of insulating material. An electrode is positioned onto or above the second layer of insulating material. In some embodiments, the device is a Metal-Insulator-FeS-Insulator-Semiconductor (MIFIS) device that allows for controlled switching of the semiconducting ferroelectric (FeS) layer between various polarization states. Switching polarization states is enabled by application of an electric field by the electrode.

### RELATED APPLICATION

The present disclosure is part of a non-provisional patent application claiming the priority benefit of U.S. Patent Application No. 63/161,113, filed on Mar. 15, 2021; U.S. Patent Application No. 63/161,125, filed on Mar. 15, 2021; U.S. Patent Application No. 63/161,135, filed on Mar. 15, 2021; and U.S. Patent Application No. 63/212,959, filed on Jun. 21, 2021; all of which are hereby incorporated by reference in their entirety.

### FIELD OF THE INVENTION

A semiconducting ferroelectric device able to be manufactured at low temperatures and utilized in electronic memory systems is described. In some embodiments, the device allows for controlled switching of a ferroelectric layer between various polarization states.

### BACKGROUND

Ferroelectric insulator materials that exhibit polarization are available. Such polarization can be reoriented by ion displacement in the crystal into two or more nonvolatile states that can be controllably switched between using an external electric field. Unfortunately, such devices can have short polarization state retention time, in part because charge accumulation at the ferroelectric insulator and semiconductor interface lead to threshold voltage drift. Further, ferroelectric insulator materials often cannot be satisfactorily annealed below 450 degrees C., which is a typical requirement for devices with channel lengths less than 90 nm. Devices with better polarization state control that are readily manufacturable are needed.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1A is a schematic representation of a semiconducting ferroelectric device;

FIG. 1B is a schematic representation of a semiconducting ferroelectric device with interface buffer layers between a semiconducting ferroelectric layer and insulator layers;

FIG. 1C is a schematic representation of a semiconducting ferroelectric device with interface buffer layers between a multilayer semiconducting ferroelectric layer and multilayer insulator layers;

FIG. 2 is a schematic representation of a process for manufacture of an improved semiconducting ferroelectric device; and

FIG. 3 illustrates a plurality of devices connected to at least one controller able to force polarization state changes in devices and allow for read of device state.

### DETAILED DESCRIPTION

Reference will now be made in detail to the described embodiments, examples of which are illustrated in the accompanying drawings. To the extent possible, in the Figures similar structures will be identified using similar reference characters. It will be understood that the Figures are presented for the purpose of describing particular embodiments of the invention and are not intended to limit the invention thereto.

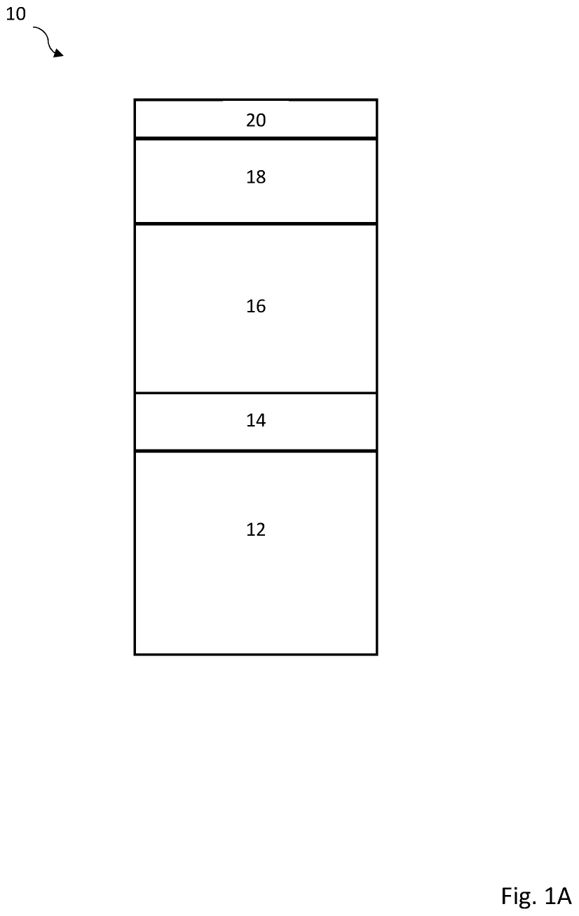

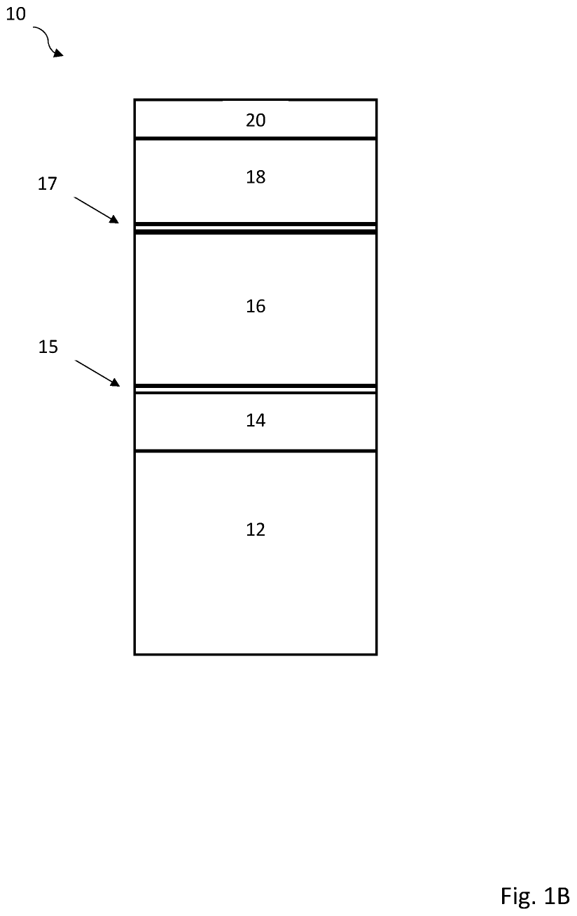

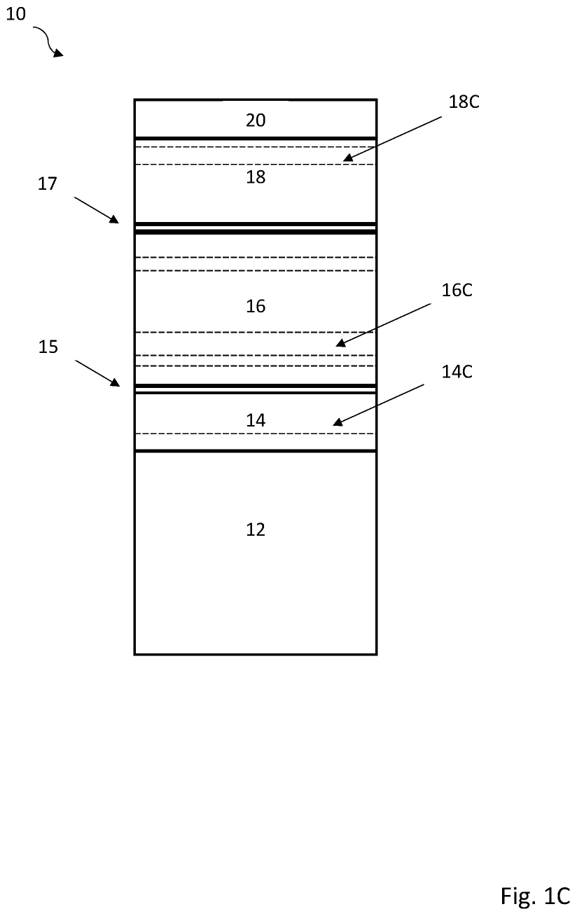

FIG. 1A shows a schematic representation of an embodiment of semiconducting ferroelectric device stack 10. The semiconducting ferroelectric device stack 10 includes a substrate 12 having a formed or deposited first insulator layer 14. A semiconducting ferroelectric layer 16 having spontaneous or induced polarization is situated on or above the first insulator layer 14. A second insulator layer 18 is situated on or above the semiconducting ferroelectric layer 16. An electrode 20 can be deposited on or above the second insulator layer 18. In one embodiment, the semiconducting ferroelectric layer 16 is electrically isolated from the substrate 12 and the electrode 20 due to its position between first insulator layer 14 and second insulator layer 18. In some embodiments the substrate 12 can be formed in whole or in part from semiconducting material.

FIG. 1B is similar to device stack 10 of FIG. 1A, but further illustrates two buffer layers 15 and 17 positioned respectively between the insulator layers 14 and 18, and the semiconducting ferroelectric layer 16. The material of the buffer layers 15 and 17 can be selected to improve layer adhesion, provide lattice matching, or allow for deposition of disparate material. In some embodiments, the buffer layers 15 and 17 can be used to modify electrical properties. In some embodiments the buffer layers 15 and 17 can be insulators. For example, in one embodiment buffer layer 15 can be formed from 0.1 to 4 nm thick, while buffer layer 17 can be formed from 0.1 to 4 nm thick. Buffer layers 15 and 17 can be respectively formed during deposition, by thermal or laser processing, or through ion implantation. In some embodiments metal organic chemical vapor deposition, atomic layer deposition, pulse laser deposition, sputtering, or the other techniques can be used to form multilayers within the insulator or semiconducting ferroelectric layers.

FIG. 1C is similar to device stack 10 of FIGS. 1A and 1B, but illustrates use of compositionally, dopant, or crystal structure distinct multilayers 14C, 18C, and 16C for respective insulator layers 14 and 18, and the semiconducting ferroelectric layer 16. Such multilayers can improve deposition, material, or electrical characteristics, and can be formed during deposition, thermal or laser processing, or through ion implantation. In some embodiments metal organic chemical vapor deposition, atomic layer deposition, pulse laser deposition, sputtering, or the other techniques can be used to form multilayers within the insulator or semiconducting ferroelectric layers.

In one embodiment of operation, semiconducting ferroelectric device stack 10 of FIGS. 1A, 1B, and 1C is a Metal-Insulator-FeS-Insulator-Semiconductor (MIFIS) device that allows for controlled switching of the semiconducting ferroelectric (FeS) layer between various polarization states. Switching polarization states is enabled by application of an electric field by electrode 20. Additionally, identity of the polarization state is detectable using circuitry (not shown) connected to the electrode 20. In some embodiments, polarization state is retained indefinitely until it is actively switched using electrode 20, making the semiconducting ferroelectric device stack 10 suitable for use in non-volatile memory applications. As an example, the semiconducting ferroelectric device stack 10 can be a component of non-volatile flash memory device utilizing semiconducting ferroelectric layer 16 as a floating gate in a floating-gate field-effect metal oxide transistor. In some embodiments, electric fields below about 2 MV/cm can be used for changing polarization of the semiconducting ferroelectric layer 16. In other embodiments, electric fields below about 100 kV/cm can be used for changing polarization of the semiconducting ferroelectric layer 16. In still other embodiments, electric fields ranging between 100 kV/cm and 500 kV/cm can be used for changing polarization of the semiconducting ferroelectric layer 16. For ease of manufacturability in CMOS fabrication facilities, materials forming the semiconducting ferroelectric layer 16 can be annealed at temperatures less than 450 degrees C.

In some embodiments, the substrate 12 includes a semiconductor that can be crystal silicon, crystal germanium, silicon carbide, silicon-on-insulator (SOI) or silicon-on-sapphire (SOS) technology, doped and/or undoped semiconductors, epitaxial layers of silicon supported by a base semiconductor foundation, conventional metal oxide semiconductors (CMOS), and/or other semiconductor structures and/or technologies. In some embodiments, the substrate 12 can act as a semiconductive substrate. The substrate 12 can be biased or maintained at zero bias. The substrate can additionally support various circuitry, such as driver and/or decode circuitry, for example, associated with of one or more device stacks formed in and/or on substrate 12. Furthermore, when reference is made to a “substrate” in the following description, previous process steps may have been utilized to form regions and/or junctions in the base semiconductor structure or foundation.

In some embodiments, the first insulator layer 14 can include dielectrics such as deposited metal oxides or nitrides. Metal oxides or nitrides can include single, mixed, or layered oxides or nitrides. In some embodiments, hafnium, zirconium, lanthanum, yttrium, aluminum, magnesium and/or manganese oxides can be used. Alternatively or in addition aluminum nitride, hafnium nitride, and mixed nitride of aluminum and hafnium can be used. In some embodiments, a composition such as Hf₍₁₋ₓ₎ZrₓO₂, where 0≤x≤1 can be used.

The first insulator layer 14 can have thickness ranging from 0.1 to 10 nm, with exact thickness depending on device stack size and application. The first insulator layer 14 can be formed by metal organic chemical vapor deposition, atomic layer deposition, pulse laser deposition, sputtering, or the other techniques.

In some embodiments, the semiconducting ferroelectric layer 16 can include one or more layers of a polarizable ferroelectric semiconducting material and typically has a thickness ranging from 1 to 80 nm. In some embodiments, thickness of the semiconducting ferroelectric layer 16 is greater than thickness of either the first insulator layer 14 or the second insulator layer 18. Typically, application of an applied electric field between electrode 20 and substrate 12 (acting as a semiconductive electrode) of less than 2 MV/cm is sufficient to modify polarity of the ferroelectric semiconducting material. In certain embodiments, an applied electric field between electrode 20 and substrate 12 of less than 2 MV/cm can be accomplished using an applied voltage less than 3V.

In some embodiments the semiconducting ferroelectric layer 16 can be formed from inorganic polycrystalline, ceramic, or crystalline materials, as well as organic polymeric materials such as polyvinylidene fluoride. In one embodiment the semiconducting ferroelectric layer 16 includes a material based on a ferroelectric ceramic, thin or thick film ferroelectric, or single crystal structure ferroelectric. Ferroelectric ceramics can be formed by using one or more combinations of films of strontium, bismuth, tantalum and oxygen, films of calcium, strontium, bismuth, tantalum and oxygen, films of strontium, bismuth, tantalum, niobium and oxygen, films of calcium, strontium, bismuth, tantalum, niobium and oxygen, films of bismuth, titanium and oxygen, films of bismuth, tantalum, titanium and oxygen, or films of bismuth, neodymium, titanium and oxygen. Alternatively or in addition, chemical solution deposition, metalorganic chemical vapor deposition (MOCVD), sputtering, laser ablation, or atomic layer deposition can be used.

In some embodiments, the ferroelectric ceramic can include a ferroelectric oxide having a crystal structure isomorphous with perovskite (CaTiO₃). Perovskites can have the general formula ABO₃, where A and B are cations. A-site cations can include Na⁺, K⁺, Na⁺, Ba²⁺, Sr²⁺, Pb²⁺, Bi³⁺, and Ca²⁺, while B-site cations can include Nb⁺, Ta⁵⁺, Zr⁴⁺, Ti⁴⁺, Pb⁴⁺, Sc³⁺, and Fe³⁺. Examples of ferroelectric ceramic oxide perovskites can include but are not limited to BaTiO₃, PbTiO₃, NaNbO₃, KNbO₃, KTaO₃, BiScO₃, and BiScO₃. In some embodiments, cation substituents can be made, allowing ceramic solid solutions of, for example, BaTiO₃ with PbTiO₃ or BaTiO₃ with CaTiO₃. In addition to simple perovskites with a general ABO₃ composition, a ferroelectric ceramic can be formed from complex perovskites where A and B sites are occupied by ions of a different valency in a fixed molar ratio. Examples include but are not limited to PbMg_{1/3}Nb_{2/3}O₃ (PMN), PbSc_{1/2}Ta_{1/2}O₃, and Bi_{1/2}Na_{1/2}TiO₃.

Alternatively, ferroelectric oxides can include ilmenite ferroelectrics having a general ABO3 composition, but where the A cation is too small to fill the coordinated site of the perovskite structure. Ilmenite structure is made up of hexagonal close-packed layers of oxygen ions, and with the A and B ions occupying the octahedrally coordinated sites between the layers. Examples include but are not limited to LiNb2O3 or LiTa2O3. In some embodiments, other classes of ferroelectric oxide materials including tungsten bronze ferroelectrics, Aurivillius compounds, phosphate ferroelectrics, or oxygen tetrahedral ferroelectrics can also be used.

Ferroelectric ceramics or oxides can be modified by introduction of substituent or modifier atoms that act to adjust various material and electrical properties by replacement of some relatively small number of cation sites with other types of cations. For example, a standard wide band insulating ferroelectric such as PZT (PbZr₍₁₋ₓ₎Ti₍ₓ₎O₃) can have various ratios of Zr to Ti modify the ferroelectric and other properties of the material. In those cases of PZT modification, for example, care is taken not to allow the material to become a semiconducting ferroelectric for the reason that the ferroelectric properties can be severely deteriorated. In the case of the semiconducting layer 16, the semiconductor ferroelectric can be designed to achieve high polarization and yet remain semiconducting for the low temperature annealing below 450 C. In the case of materials that can be made semiconducting ferroelectric, for example, with Bi₂O₃ added in quantities between 1%-20% of Bi₄Ti₃O₁₂ or other Bismuth based Aurivillius ferroelectrics, a large increase in semiconducting properties can be tailored in such a way that the internal screening of the spontaneous or induced polarization by free carriers such as electrons and holes, can be controlled. In such cases the semiconducting ferroelectric layer 16 can also be enhanced in spontaneous polarization by the addition of polarization enhancement modifiers such as Nb, La, Ta, Zr, Dy, Sm, Cr, Sb, Fe, Si, Al, Pb, Hf, Ba, or Cd in quantities from 1% to 20%. Substitution or modification can occur along with, or after deposition of the semiconducting ferroelectric layer 16, and substitution levels in the semiconducting ferroelectric layer 16 can be uniform, increasing/decreasing, or have custom percentage levels at each atomic layer in the formed semiconducting ferroelectric layer 16

Ferroelectric ceramics or oxides can be changed in conductivity and influence the overall polarization due to screening by introduction of small amounts of dopant atoms that act to adjust various material and electrical properties. For example, the semiconducting ferroelectric layer 16 can be doped to have at most 1% of one of Dy, Sm, Sc, Cr, Sb, Fe, Si, Al, Ga, Ge, Hf, Ba or Y. Doping can occur along with or after deposition of the semiconducting ferroelectric layer 16, and dopant levels in the semiconducting ferroelectric layer 16 can be uniform, increasing/decreasing, or have custom doped levels at each atomic layer in the formed ferroelectric layer 16. For example, in some embodiments the semiconducting ferroelectric layer 16 can be highly doped with Nb for a first portion, doped with a combination of Nb and Ta in a second portion, and finally doped with lesser amounts of Nb in a third portion.

In some embodiments, a ferroelectric ceramic oxide can include a single layer of a bismuth based ceramic such as bismuth titanate doped with transition metals and rare earth dopants, such as Nb, La, Ta, Zr, Dy, Sm, Cr, CrSb, Fe, Si, Al, Pb, Hf, Ba, or Cd can be used. In some embodiments Bi₄Ti₃O₁₂ doped with less than 15% by atomic mass of BixO_{y}, where 1≤x≤2, and 1≤y≤3 (BiO or Bi₂O₃) can be used. Other embodiments include strontium bismuth tantalum oxide (SrBi₂Ta₂O₉) material, a strontium bismuth tantalum niobium oxide (SrBi₂[Ta₍₁₋ₓ₎,Nbₓ]₂O₉, where 0<x<1) material, a bismuth lanthanum titanium oxide ([Bi, La]₄Ti₃O₁₂) material, or the like. In other embodiments, semiconducting ferroelectric layer 16 can be formed from multiple layers that include but are not limited to bismuth based ceramics.

In some embodiments, the second insulator layer 18 can include dielectrics such as deposited metal oxides or nitrides. Metal oxides or nitrides can include single, mixed, or layered oxides or nitrides. In some embodiments, hafnium, zirconium, lanthanum, yttrium, aluminum, magnesium and/or manganese oxides can be used. Alternatively or in addition aluminum nitride, hafnium nitride, and mixed nitride of aluminum and hafnium can be used. In some embodiments, a composition such as Hf₍₁₋ₓ₎Zr₍ₓ₎O₂, where 0≤x≤1 can be used.

The second insulator layer 18 can have thickness ranging from 0.5 to 10 nm, with exact thickness depending on device stack size and application. The second insulator layer 18 can be formed by metal organic chemical vapor deposition, atomic layer deposition, pulse laser deposition, sputtering, or the other techniques. In some embodiments, composition or thickness of the second insulator layer 18 can be the same or similar to that of first insulator layer 14.

In some embodiments, the electrode 20 can include materials capable of carrying electric current and providing charge to the semiconducting ferroelectric layer 16. In some embodiments, metals can be used. Metals can include pure metals, metal alloys, or layered metals. In some embodiments titanium, aluminum, or titanium/aluminum alloys can be used. In some embodiments, doped or undoped polycrystalline silicon can be the top electrode.

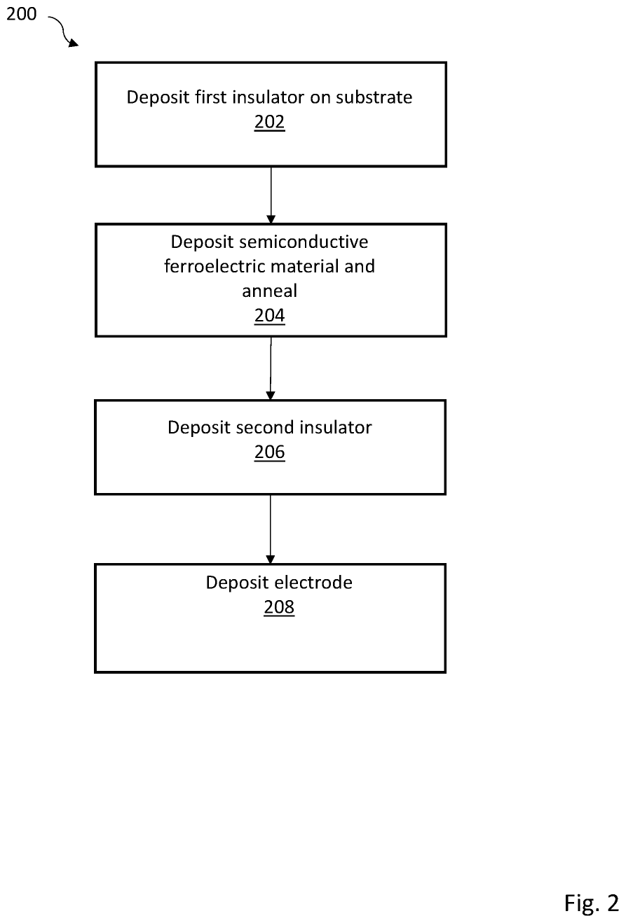

FIG. 2 shows a schematic representation of a process embodiment for manufacture of device stack such as illustrated with respect to FIG. 1. In this embodiment a substrate is provided to support deposit of a first insulator layer (step 202). Deposition can be directly on the substrate or can be on one or more buffer layers selected to improve layer adhesion, provide lattice matching, or allow for deposition of disparate material. In some embodiments, the first insulator layer can include multiple layers that are compositionally or structurally distinct. Next, after optional deposition of buffer layer(s), a semiconducting ferroelectric layers is deposited and annealed at a temperature below 450 degrees Celsius (step 204). Annealing can be immediate, or after further deposition of additional materials. A second layer of insulating material can be deposited onto or above the semiconducting ferroelectric layer (step 206). An electrode can be deposited onto or above the second layer of insulating material.

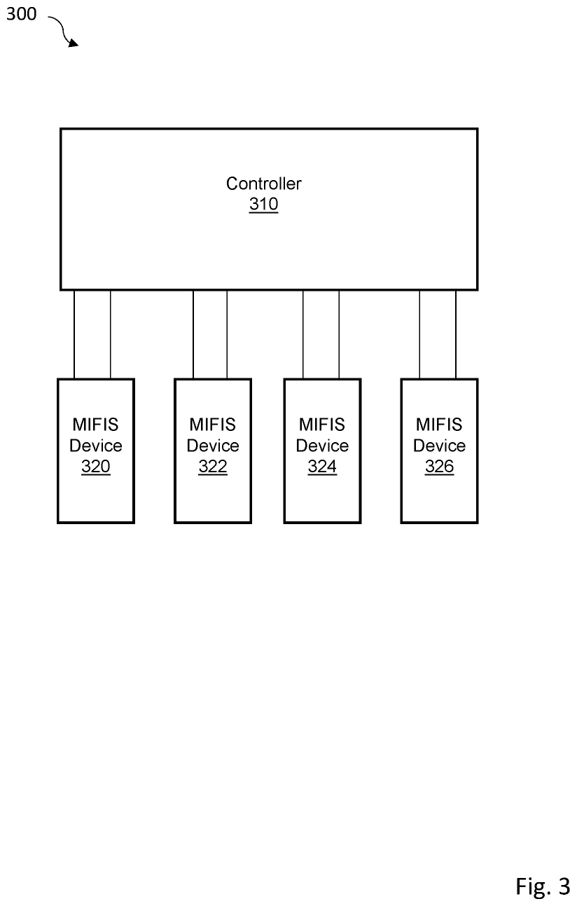

FIG. 3 shows a schematic representation of a system including a controller 310 for a plurality of MIFIS devices 320, 322, 324, and 326. Each MIFIS device includes one or more polarization modifiable device stacks such as disclosed herein. In this embodiment, the MIFIS devices 320, 322, 324, and 326 include a substrate supporting first and second layers of insulating material, with the first layer of insulating material supported by the substrate. A semiconducting ferroelectric layer that is positioned and electrically isolated between the first and second layers of insulating material, which also have an electrode positioned onto or above the second layer of insulating material. The controller 310 can be operated to read or change polarization state of the semiconducting ferroelectric layer using the electrode.

Having described the general details of embodiments of the present invention, the following examples provide additional details.

### EXAMPLE 1

In one embodiment, a device such as disclosed with respect to FIG. 1 includes a polarizable ferroelectric semiconducting material that includes Bi₄Ti₃O₁₂ doped with less than 15% by atomic mass of BiₓO_{y}, where 1≤x≤2, and 1≤y≤3 (BiO or Bi₂O₃).

### EXAMPLE 2

Thin films (≤30 nm) of doped or undoped Bi₄Ti₃O₁₂ were prepared by atomic layer deposition on a 5 nm film of HfO₂ and covered with a 5 nm film of HfO₂ before a step of rapid thermal annealing at 450 C for 1 min. under nitrogen.

The foregoing description of the invention has been presented for purposes of illustration and description and is not intended to be exhaustive or to limit the invention to the precise form disclosed, and obviously many modifications and variations are possible in light of the above teaching. The embodiments were chosen and described in order to best explain the principles of the invention and its practical application to thereby enable others skilled in the art to best utilize the invention in various embodiments and with various modifications as are suited to the particular use contemplated

1. A device stack, comprising:
a substrate;
first and second layers of insulating material, with the first layer of insulating material supported by the substrate;
a semiconducting ferroelectric layer that is positioned and electrically isolated between the first and second layers of insulating material; and
an electrode positioned onto or above the second layer of insulating material.

2. The device stack of claim 1, wherein the semiconducting ferroelectric layer has spontaneous polarization.

3. The device stack of claim 1, wherein the semiconducting ferroelectric layer includes a ceramic material with a semiconducting ferroelectric perovskite crystal structure.

4. The device stack of claim 1, wherein the substrate is a semiconducting substrate.

5. The device stack of claim 1, wherein the semiconducting ferroelectric layer has at least one substituent or a Nb, La, Ta, Zr, Dy, Sm, Cr, Sb, Fe, Si, Al, Pb, Hf, Ba, or Cd with at least an amount greater than 1 At %.

6. The device stack of claim 1, wherein the semiconducting ferroelectric layer is doped with at most 1 At % of one of Dy, Sm, Sc, Cr, Sb, Fe, Si, Al, Ga, Ge, Hf, Ba, or Y.

7. A method for forming a device stack, comprising:
providing a substrate;
depositing a first layer of insulating material onto or above the substrate;
depositing a semiconducting ferroelectric layer onto or above the first layer of insulating material;
depositing a second layer of insulating material onto or above the semiconducting ferroelectric layer; and
positioning an electrode onto or above the second layer of insulating material.

8. The method for forming a device stack of claim 7, wherein the semiconducting ferroelectric layer has spontaneous polarization.

9. The method for forming a device stack of claim 7, wherein the semiconducting ferroelectric layer includes a ceramic material with a semiconducting ferroelectric perovskite crystal structure.

10. The method for forming a device stack of claim 7, wherein the substrate is a semiconducting substrate.

11. The method for forming a device stack of claim 7, further comprising the step of processing the semiconducting ferroelectric layer to provide at least one substituent or a modifier comprising Nb, La, Ta, Zr, Dy, Sm, Cr, Sb, Fe, Si, Al, Pb, Hf, Ba, or Cd, with at least an amount greater than 1 At %.

12. The method for forming a device stack of claim 7, further comprising the step of doping the semiconducting ferroelectric layer with at most 1 At % of one of Dy, Sm, Sc, Cr, Sb, Fe, Si, Al, Ga, Ge, Hf, Ba, or Y.

13. A method for forming a CMOS processing compatible device stack, comprising:
providing a substrate;
depositing a first layer of insulating material onto or above the substrate;
at a temperature below 450 degrees Celsius, depositing and then annealing a semiconducting ferroelectric layer onto or above the first layer of insulating material;
depositing a second layer of insulating material onto or above the ferroelectric layer; and
positioning an electrode onto or above the second layer of insulating material.

14. The method for forming a CMOS processing compatible device stack of claim 13, wherein the semiconducting ferroelectric layer has spontaneous polarization.

15. The method for forming a CMOS processing compatible device stack of claim 13, wherein the semiconducting ferroelectric layer includes a ceramic material with a semiconducting ferroelectric perovskite crystal structure.

16. The method for forming a CMOS processing compatible device stack of claim 13, wherein the substrate is a semiconducting substrate.

17. The method for forming a CMOS processing compatible device stack of claim 13, further comprising the step of processing the semiconducting ferroelectric layer to provide at least one substituent or a modifier comprising Nb, La, Ta, Zr, Dy, Sm, Cr, Sb, Fe, Si, Al, Pb, Hf, Ba, or Cd, with at least an amount greater than 1 At %.

18. The method for forming a CMOS processing compatible device stack of claim 13, further comprising the step of doping the semiconducting ferroelectric layer with at most 1 At % of one of Dy, Sm, Sc, Cr, Sb, Fe, Si, Al, Ga, Ge, Hf, Ba or Y.

19. A device stack, comprising:
a semiconducting substrate;
first and second layers of insulating material, with the first layer of insulating material supported by the substrate;
a semiconducting ferroelectric layer that is positioned in electrical isolation between the first and second layers of insulating material; and
wherein both the first and second layers of insulating material respectively have a thickness less than a thickness of the semiconducting ferroelectric layer.

20. A method for forming a CMOS processing compatible device stack, comprising:
providing a semiconducting substrate;
depositing a first layer of insulating material onto or above the substrate wherein the first layer of insulating material is formed to have a thickness ranging between 0.1 and 10 nanometers;
at a temperature below 450 degrees Celsius, depositing and then annealing a semiconducting ferroelectric layer onto or above the first layer of insulating material;
depositing a second layer of insulating material onto or above the ferroelectric layer wherein the second layer of insulating material is formed to have a thickness ranging between 0.5 to 10 nm.

21. A device stack, comprising:
a substrate able to act as a first electrode;
first and second layers of insulating material, with the first layer of insulating material supported by the substrate;
an electrically isolated semiconducting ferroelectric layer that acts as a floating gate positioned between the first and second layers of insulating material; and
a second electrode positioned above the second layer of insulating material and able to apply an electric field between the first and second electrode of sufficient strength to change polarity of the semiconducting ferroelectric layer.

22. A method for forming a CMOS processing compatible device stack, comprising:
providing a substrate able to act as a first electrode;
depositing a first layer of insulating material onto or above the substrate;
at a temperature below 450 degrees Celsius, depositing and then annealing a semiconducting ferroelectric layer having spontaneous polarization onto or above the first layer of insulating material;
depositing a second layer of insulating material onto or above the ferroelectric layer; and
positioning a second electrode onto or above the second layer of insulating material, with the second electrode arranged to apply an electric field of less than 2 MV/cm between the first and second electrode of sufficient strength to change polarity of the semiconducting ferroelectric.

23. A device stack, comprising:
first and second layers of insulating material; and
an electrically isolated semiconducting ferroelectric layer having spontaneous polarization and positioned in contact with each of the first and second layers of insulating material.

24. A method for forming a CMOS processing compatible device stack, comprising:
providing a substrate;
depositing a first layer of insulating material onto or above the substrate;
at a temperature below 450 degrees Celsius, depositing and then annealing a semiconducting ferroelectric layer having spontaneous polarization onto or above the first layer of insulating material; and
depositing a second layer of insulating material onto or above the ferroelectric layer.
